(19) United States
(12) Patent Application Publication
(10) Pub. No.: US 2019/0001643 A1
(43) Pub. Date: Jan. 3, 2019

(54) GAS BARRIER FILM AND METHOD OF PRODUCING GAS BARRIER FILM

(71) Applicant: FUJIFILM Corporation, Tokyo (JP)

(72) Inventor: Aya NAKAYAMA, Ashigarakami-gun (JP)

(73) Assignee: FUJIFILM Corporation, Tokyo (JP)

(21) Appl. No.: 16/047,380

(22) Filed: Jul. 27, 2018

Related U.S. Application Data
(63) Continuation of application No. PCT/JP2016/085997, filed on Dec. 5, 2016.

(30) Foreign Application Priority Data
Jan. 29, 2016 (JP) 2016-016091
Nov. 15, 2016 (JP) 2016-222343

(51) Int. Cl. B32B 27/28; B32B 17/10; B05D 3/06; B05D 7/04

(52) U.S. Cl. CPC B32B 27/28; B32B 17/10807; B05D 3/061; B05D 7/04; B32B 2250/03; B32B 2250/04; C23C 16/30; B32B 2255/20; B32B 2307/7242; B32B 2309/68; B32B 2310/0831; B32B 2313/00; B05D 2518/12; B32B 2255/10

(57) ABSTRACT

A gas barrier film includes, in order, a film substrate, an organic layer, and a silica layer, in which the silica layer includes a silica polymer having at least a covalent bond between a silicon atom and an oxygen atom, and a concentration of carbon atoms of the organic layer is 50% or more. A method of producing a gas barrier film includes forming an organic layer having a concentration of carbon atoms of 50% or more on a film substrate, applying a coating liquid including a silicon compound to the organic layer to form a layer including the silicon compound, and irradiating the layer including the silicon compound with vacuum ultraviolet rays to form a silica layer including a silica polymer having at least a covalent bond between a silicon atom and an oxygen atom.

### CROSS-REFERENCE TO RELATED APPLICATIONS

This application is a Continuation of PCT International Application No. PCT/JP2016/085997, filed on Dec. 5, 2016, which claims priority under 35 U.S.C. § 119(a) to Japanese Patent Application No. 2016-016091, filed on Jan. 29, 2016, and Japanese Patent Application No. 2016-222343, filed on Nov. 15, 2016. Each of the above application(s) is hereby expressly incorporated by reference, in its entirety, into the present application.

### BACKGROUND OF THE INVENTION

### 1. Field of the Invention

The present invention relates to a gas barrier film and a method of producing a gas barrier film.

### 2. Description of the Related Art

As a gas barrier film, in the related art, a film in which an inorganic layer is formed on a surface of a plastic film has been known. In recent years, as seen from JP5741489B or JP2013-39786A, a gas barrier film including a gas barrier layer obtained by subjecting a coating film of a polysilazane solution that is known as a glass coating agent to a vacuum ultraviolet irradiation treatment has been also developed. In the gas barrier film disclosed in JP5741489B or JP2013-39786A, a layer formed of silica particles and resin or a layer formed of polysiloxane is provided between the gas barrier layer and a substrate so that durability and high barrier properties can be maintained.

### SUMMARY OF THE INVENTION

As a result of studies on the gas barrier film disclosed in JP5741489B or JP2013-39786A conducted by the present inventors, an example in which barrier properties are deteriorated under a high temperature and high humidity environment has been found. An object of the present invention is to provide a gas barrier film exhibiting high barrier properties even under a high temperature and high humidity environment as a gas barrier film including a silica layer formed by using a coating film of a polysilazane solution or the like, and a method of producing the same.

In order to achieve the object, the present inventors have conducted various studies on a layer that is provided between a gas barrier layer and a substrate and have assumed that in the layer disclosed in JP5741489B or JP2013-39786A, adsorbed water of silica particles is released under a high temperature environment or an unreacted portion in polysiloxane undergoes reaction to release alcohol or water, and thus deterioration of the gas barrier layer causes deterioration of barrier properties of the gas barrier film. The present inventors have conducted further studies based on this assumption and have found a preferable composition for a layer that is provided between the gas barrier layer and the substrate. Thus, the present invention has been completed.

That is, the present invention provides the following [1] to [16].

[1] A gas barrier film comprising, in order: a film substrate; a first organic layer; and a silica layer,

in which the silica layer includes a silica polymer having at least a covalent bond between a silicon atom and an oxygen atom, and

a concentration of carbon atoms of the first organic layer is 50% or more.

[2] The gas barrier film according to [1], in which the first organic layer is in direct contact with the silica layer.

[3] The gas barrier film according to [1] or [2], further comprising:

an inorganic layer,

in which the first organic layer is in direct contact with the inorganic layer.

[4] The gas barrier film according to [1] or [2], further comprising:

an inorganic layer,

in which the film substrate, the first organic layer, the silica layer, and the inorganic layer are provided in this order.

[5] The gas barrier film according to [3] or [4], in which the inorganic layer is a vapor deposition layer.

[6] The gas barrier film according to any one of [1] to [5], in which an atomic number ratio of the first organic layer is O/C=0.050 to 1.0 and Si/C=0.00 to 0.10.

[7] The gas barrier film according to any one of [1] to [6], in which a film thickness of the first organic layer is 0.5 to 10 μm.

[8] The gas barrier film according to any one of [1] to [7], in which a film thickness of the silica layer is 50 to 1000 nm.

[9] The gas barrier film according to any one of [1] to [8], in which an atomic number ratio of the silica layer is Si:O:N=1:0.1 to 1.2:0.5 to 1.5.

[10] The gas barrier film according to [1] or [2], further comprising:

an inorganic layer; and

a second organic layer,

in which the film substrate, the first organic layer, the silica layer, the inorganic layer, and the second organic layer are provided in this order, and

a concentration of carbon atoms of the second organic layer is 50% or more.

[11] A method of producing a gas barrier film comprising:

forming an organic layer having a concentration of carbon atoms of 50% or more on a film substrate;

applying a coating liquid including a silicon compound to the organic layer to form a coating layer including the silicon compound; and

irradiating the coating layer including the silicon compound with vacuum ultraviolet rays to form a silica layer including a silica polymer having at least a covalent bond between a silicon atom and an oxygen atom.

[12] The method of producing a gas barrier film according to [11],

in which the applying of the coating liquid includes applying the coating liquid to a surface of the organic layer and

the method further comprises forming an inorganic layer on a surface of the silica layer by a vapor deposition method or a sputtering method.

[13] The method of producing a gas barrier film according to [11], further comprising:

forming an inorganic layer on a surface of the organic layer by a vapor deposition method or a sputtering method,

in which the applying of the coating liquid includes applying the coating liquid to a surface of the inorganic layer.

[14] The method of producing a gas barrier film according to [12] or [13],

in which the inorganic layer is formed by a chemical vapor deposition method.

[15] The method of producing a gas barrier film according to any one of [11] to [14],

in which the silicon compound is perhydropolysilazane.

[16] The method of producing a gas barrier film according to any one of [11] to [15],

in which an atomic number ratio of the organic layer is O/C=0.050 to 1.0 and Si/C=0 to 0.1.

According to the present invention, it is possible to provide a gas barrier film exhibiting high barrier properties even under a high temperature and high humidity environment and a method of producing the same.

### DESCRIPTION OF THE PREFERRED EMBODIMENTS

Hereinafter, the contents of the present invention will be described in detail. In the present specification, “to” is used to mean that numerical values described before and after “to” are included in a numerical range as a lower limit value and an upper limit value. In the present specification, “(meth)acrylate” represents “either or both of acrylate and methacrylate”. The same shall be applied to “(meth)acryloyl group” and the like.

<Gas Barrier Film>

A gas barrier film of the present invention includes a film substrate, an organic layer, and a silica layer in this order. It is preferable that the gas barrier film of the present invention further includes an inorganic layer. The inorganic layer is preferably included in the gas barrier film such that the organic layer, the silica layer, and the inorganic layer are arranged in this order or the organic layer, the inorganic layer, and the silica layer are arranged in this order, and more preferably included in the gas barrier film such that the organic layer, the silica layer, and the inorganic layer are arranged in this order. In the gas barrier film of the present invention, it is preferable that the organic layer is in direct contact with the silica layer, or an inorganic layer is further provided and the organic layer is in direct contact with the inorganic layer.

The gas barrier film of the present invention may include other layers. For example, it is preferable that the gas barrier film further includes a second organic layer. The gas barrier film of the present invention may include two or more silica layers, may include two or more inorganic layers, or may be formed by alternately laminating two or more silica layers and two or more inorganic layers.

Preferable examples of the layer configuration of the gas barrier film include the following layer configurations. The layers are laminated in the described orders of:

film substrate/organic layer/silica layer; film substrate/organic layer/silica layer/inorganic layer; film substrate/organic layer/inorganic layer/silica layer; film substrate/organic layer/silica layer/silica layer; film substrate/organic layer/silica layer/inorganic layer/silica layer; film substrate/organic layer/inorganic layer/silica layer/inorganic layer; film substrate/organic layer/inorganic layer/silica layer/silica layer; film substrate/organic layer/inorganic layer/silica layer/inorganic layer/silica layer; film substrate/organic layer/silica layer/inorganic layer/silica layer/inorganic layer; film substrate/organic layer/silica layer/silica layer/inorganic layer/inorganic layer; film substrate/organic layer/inorganic layer/inorganic layer/silica layer/silica layer; film substrate/organic layer/silica layer/inorganic layer/silica layer/inorganic layer/silica layer; film substrate/organic layer/inorganic layer/organic layer/silica layer/inorganic layer;

film substrate/organic layer/silica layer/second organic layer; film substrate/organic layer/silica layer/inorganic layer/second organic layer; film substrate/organic layer/inorganic layer/silica layer/second organic layer; film substrate/organic layer/silica layer/silica layer/second organic layer; film substrate/organic layer/silica layer/inorganic layer/silica layer/second organic layer; film substrate/organic layer/inorganic layer/silica layer/inorganic layer/second organic layer; film substrate/organic layer/inorganic layer/silica layer/inorganic layer/silica layer/second organic layer; film substrate/organic layer/silica layer/inorganic layer/silica layer/inorganic layer/second organic layer; film substrate/organic layer/silica layer/inorganic layer/silica layer/inorganic layer/silica layer; and film substrate/organic layer/inorganic layer/organic layer/silica layer/inorganic layer/second organic layer.

Among these, configurations of film substrate/organic layer/silica layer/inorganic layer; film substrate/organic layer/silica layer/silica layer; film substrate/organic layer/silica layer/inorganic layer/silica layer; film substrate/organic layer/inorganic layer/silica layer/silica layer; film substrate/organic layer/silica layer/inorganic layer/silica layer/inorganic layer; film substrate/organic layer/silica layer/inorganic layer/silica layer/inorganic layer/silica layer; film substrate/organic layer/inorganic layer/silica layer/inorganic layer; and film substrate/organic layer/inorganic layer/silica layer/inorganic layer/silica layer are particularly preferable.

The number of layers constituting the gas barrier film is not particularly limited but is typically preferably 3 to 10 and more preferably 4 to 7. The gas barrier film of the present invention may have a functional layer other than the film substrate, the organic layer, the inorganic layer, and the silica layer. The functional layer is described in detail in paragraphs 0036 to 0038 of JP2006-289627A. Examples of functional layers other than these functional layers include a matting agent layer, a solvent resistant layer, an antistatic layer, a flattening layer, an adhesiveness improving layer, a light shielding layer, an antireflection layer, a hard coat layer, a stress relaxing layer, an antifogging layer, an antifouling layer, and a layer to be printed.

The film thickness of the gas barrier film is preferably 10 μm to 200 μm and more preferably 20 μm to 150 μm.

The gas barrier film of the present invention is a gas barrier film exhibiting high barrier properties even under a high temperature and high humidity environment. The water vapor transmission rate [g/m²·day] before and after a moisture and heat test in which the gas barrier film of the present invention is left to stand under the condition of 85° C. and 85% RH for 250 hours preferably satisfies Expression (A).

WVTR(0)/WVTR(1)≥0.1 (A)

WVTR(0): water vapor transmission rate immediately after preparation (before moisture and heat test)

WVTR(1): water vapor transmission rate after moisture and heat test

It is more preferable that WVTR(0)/WVTR(1)≥0.2.

[Film Substrate]

The film substrate may be a plastic film. The plastic film to be used is not particularly limited in terms of a material, thickness, or the like as long as the film can hold a laminate including an organic layer and a silica layer to be provided thereon and can be selected appropriately depending on the purpose of use or the like. Specifically, the plastic film includes thermoplastic resins such as polyester resins such as polyethylene terephthalate (PET) or polyethylene naphthalate (PEN), methacrylic resin, methacrylic acid-maleic acid copolymer, polystyrene resin, transparent fluorine-containing resin, polyimide, fluorinated polyimide resin, polyamide resin, polyamide-imide resin, polyetherimide resin, cellulose acylate resin, polyurethane resin, polyether ether ketone resin, polycarbonate resin, alicyclic polyolefin resin, polyarylate resin, polyether sulfone resin, polysulfone resin, cycloolefin copolymer, fluorene ring-modified polycarbonate resin, alicyclic-modified polycarbonate resin, fluorene ring-modified polyester resin, and acryloyl compound. As the film substrate, polyester resin can be particularly preferably used.

The film thickness of the film substrate is preferably 8 μm to 200 μm and more preferably 18 μm to 150 μm.

[Silica Layer]

The silica layer is a layer including a silica polymer having at least a covalent bond between a silicon atom and an oxygen atom. The silica layer is a layer distinguished from the inorganic layer, which will be described later, and can be confirmed as a layer of a lighter color than the inorganic layer in a case where the cross section of the gas barrier film is imaged as a transmission electron image (TEM image) with a scanning transmission electron microscope (STEM). The reason for observation of the light color is considered that the atomic density is lower than in the inorganic layer. The silica layer may be a glassy layer. The silica layer is a layer formed from a layer obtained by applying a coating liquid including the silica polymer as the raw material.

The atomic number ratio of silicon atoms (Si), oxygen atoms (O), and nitrogen atoms (N) of the silica layer is preferably Si:O:N=1:0.1 to 1.2:0.5 to 1.5 and more preferably Si:O:N=1:0.1 to 0.5:0.8 to 1.4. The atomic number ratio of silicon, oxygen, and nitrogen atoms is a value measured by an X-ray photoelectron spectroscopy method (XPS method). An XPS surface analysis device is not particularly limited and for example, ESCALAB-200R manufactured by VG Scientific can be used.

The silica layer may include a carbon atom, but it is preferable that the silica layer does not practically include a carbon atom. Specifically, it is preferable that the silica layer is a layer from which a carbon atom is not detected in the XPS method.

The silica polymer is a product obtained from a silicon compound as a raw material by irradiating the coating layer with ultraviolet rays and has at least a covalent bond between a silicon atom and an oxygen atom. The silica polymer may have a covalent bond between silicon atoms or may have a covalent bond between a silicon atom and an oxygen atom. The silica polymer is more preferably silicon oxide or silicon oxynitride. The silica polymer in the silica layer forms a polymer through three-dimensionally crosslinking by a covalent bond between atoms. Therefore, for example, it is considered that, even in a case where the silica layer and the inorganic layer, which will be described later, are common in that the layers are silicon oxide or silicon oxynitride, the steric structures of the compounds in the layers are different from each other.

The silicon compound as the raw material is a compound including a silicon atom and is preferably a compound including a silicon atom and a nitrogen atom, or a silicon atom, a nitrogen atom, and an oxygen atom. The silicon compound may be an organic compound including a carbon atom. The silicon compound is preferably an inorganic silicon compound. In addition, the silicon compound may be a polymer or may be cross-linked. The silicon compound is preferably a polymer having at least a covalent bond between a silicon atom and a nitrogen atom. Examples of the silicon compound include compounds such as polysilazane, siloxane, and polysiloxane. Specific examples include compounds described in paragraphs 0128 and 0129 of JP2015-147952A.

The silicon compound is particularly preferably perhydropolysilazane.

The silica layer is formed by using a coating liquid including a catalyst with the silicon compound and as a result, the silica layer of the gas barrier film of the present invention preferably includes the catalyst. Examples of the catalyst include an amine catalyst, a metal catalyst, a pyridine compound catalyst, and an inorganic acid catalyst. Specifically, catalysts described in paragraph 0152 of JP2014-201032A and paragraph 0064 of JP2014-2400512A may be used.

As the catalyst, an amine having a molecular weight of 200 or more and a boiling point of 230° C. or higher is particularly preferable. The present inventors have found that by using the amine having a molecular weight of 200 or more and a boiling point of 230° C. or higher as the catalyst, the barrier properties of the gas barrier film in which the inorganic layer is formed on the surface of the silica layer is less likely to be deteriorated even under a high temperature and high humidity environment. Although the present invention is not limited to a specific theory, it is considered that the amine having a molecular weight of 200 or more and a boiling point of 230° C. or higher is capable of forming a dense silica layer as a catalyst and bleed out is less likely to occur even in a case where the formed silica layer is left under a high temperature and high humidity condition. There is a possibility that the barrier properties may be deteriorated due to a reduction in the density of the silica layer depending on bleed out. In addition, particularly, in a case where the inorganic layer is formed on the surface thereof, there is a possibility that the barrier properties may be deteriorated due to deterioration in interlaminar adhesion or breakage of the inorganic layer caused by the presence of the bled-out catalyst present at the interface. In a case where the silica layer is formed by using the coating liquid including the specific amine, the barrier properties are less likely to be deteriorated even under a high temperature and high humidity condition.

Examples of the amine having a molecular weight of 200 or more and a boiling point of 230° C. or higher include trihexylamine (molecular weight: 269.5, boiling point: 265° C.), trioctylamine (molecular weight: 353.7, boiling point: 367° C.), dioctyl amine (molecular weight: 241.5, boiling point: 298° C.), and triphenylamine (molecular weight: 245.3, boiling point: 347° C.). Among these, trihexylamine, trioctylamine, or dioctyl amine is preferable.

Since the gas barrier film of the present invention include an organic layer which will be described later, even in case of a gas barrier film having a silica layer not containing an amine having a molecular weight of 200 or more and a boiling point of 230° C. or higher, higher barrier properties can be realized even under a high temperature and high humidity environment.

The film thickness of the silica layer is preferably 50 to 1000 nm, more preferably 100 to 500 nm, and even more preferably 150 to 350 nm.

The content of the silicon compound in the coating liquid including the silicon compound is preferably 94.0% by mass to 99.9% by mass and more preferably 96.0% by mass to 99.7% by mass with respect to the total mass of the solid contents of the coating liquid (mass excluding the solvent).

In a case where the coating liquid includes the catalyst, the content of the catalyst in the coating liquid is preferably 0.1% by mass to 10.0% by mass and more preferably 0.3% by mass to 5.0% by mass with respect to the total mass of the solid contents of the coating liquid (mass excluding the solvent). In a case where the catalyst is an amine having a molecular weight of 200 or more and a boiling point of 230° C. or higher, the content of the catalyst is preferably 0.1% by mass to 5.0% by mass and more preferably 0.3% by mass to 3.0% by mass with respect to the total mass of the solid contents of the coating liquid (mass excluding the solvent).

The coating liquid may include additives other than the silicon compound and the catalyst.

In addition, examples of the solvent of the coating liquid include hydrocarbon solvents such as pentane, hexane, cyclohexane, toluene, and xylene; halogen hydrocarbon solvents such as methylene chloride and trichloroethane; esters such as ethyl acetate and butyl acetate; ketones such as acetone and methyl ethyl ketone; ethers such as dibutyl ether, dioxane, and tetrahydrofuran; and aromatic hydrocarbon solvents such as SOLVESSO ((registered trademark), manufactured by Exxon Mobil Corporation). Among these, dibutyl ether, xylene, or SOLVESSO is preferable.

The coating liquid for forming the silica layer may be applied to the organic layer. Specifically, the coating liquid may be applied to a surface of the organic layer, a surface of the inorganic layer that is formed on the organic layer, or a surface of the silica layer which is formed on the organic layer.

Examples of the coating method include a spray coating method, a spin coating method, an ink jet method, a dip coating method, an air knife coating method, a curtain coating method, a roller coating method, a wire bar coating method, a gravure coating method, a slide coating method, a die coating method, a casting film forming method, a bar coating method, and a gravure printing method. Among these, a spin coating method, a wire bar coating method, a gravure coating method, or a die coating method is preferable.

In a case where the coating liquid includes a solvent, the coating liquid may be dried after application and before ultraviolet irradiation.

The silica layer is obtained by irradiating a coating layer of the coating liquid including the silicon compound with vacuum ultraviolet rays. By irradiating the coating layer with vacuum ultraviolet rays, the coating layer is modified and thus a denser layer is formed. The vacuum ultraviolet irradiation treatment may be an excimer irradiation treatment. The wavelength of the vacuum ultraviolet ray is 100 to 200 nm and preferably 100 to 180 nm. In addition, the irradiance of the vacuum ultraviolet ray is preferably 30 to 280 mW/cm² and more preferably 60 to 180 mW/cm². The exposure cumulative amount of the vacuum ultraviolet ray is preferably 10 to 10000 mJ/cm², more preferably 100 to 8000 mJ/cm², and even more preferably 200 to 6000 mJ/cm².

The vacuum ultraviolet irradiation is preferably performed in a state in which the oxygen concentration and the water vapor concentration are low, and more preferably performed in an inert gas atmosphere such as nitrogen gas. The vacuum ultraviolet irradiation may be performed under a condition of a high temperature of 60° C. to 140° C. higher than room temperature or may be performed at room temperature.

The details of the method of forming the silica layer can be referred to the description of paragraphs 0149 to 0208 of JP2014-201032A.

[Inorganic Layer]

The inorganic layer is a thin film layer formed of a metal compound.

Components included in the inorganic layer are not particularly limited as long as the components satisfy gas barrier performance. Examples of the components include a metal oxide, a metal nitride, a metal carbide, a metal oxynitride and a metal oxycarbide, and an oxide, a nitride, a carbide, an oxynitride, an oxycarbide, or the like containing one or more metals selected from Si, Al, In, Sn, Zn, Ti, Cu, Ce, and Ta can be preferably used. However, in a case where the metal compound is an oxide containing Si or an oxynitride containing Si, the metal compound is a compound different from the silica polymer. Accordingly, the steric structure of the compound in the inorganic layer and the steric structure of the compound in the silica layer are different from each other. Among these, an oxide, a nitride, or an oxynitride of a metal selected from Si, Al, In, Sn, Zn, and Ti is preferable, particularly, an oxide of Si, a nitride of Si, an oxynitride of Si, an oxide of Al, a nitride of Al, or an oxynitride of Al is preferable. These may contain other atoms as a subcomponent.

As the inorganic layer, inorganic layers including silicon (Si) are most preferable. This is because the inorganic layers have higher transparency and further excellent gas barrier properties. Among these, particularly, an inorganic layer formed of oxynitride silicon or silicon nitride is preferable.

For example, in the inorganic layer, an oxide, a nitride, or an oxynitride of a metal may contain hydrogen. However, the hydrogen concentration in Rutherford forward scattering is preferably 30% or less.

The smoothness of the inorganic layer is preferably less than 3 nm and more preferably 1 nm or less as an average roughness in 1 μm square (a square having one side of 1 μm) (Ra value).

The thickness of the inorganic layer is not particularly limited. Typically, the thickness of the single inorganic layer is in a range of 5 to 1000 nm, preferably 20 to 500 nm, and more preferably 50 to 300 nm. The single inorganic layer may have a laminated structure having a plurality of sub-layers. In this case, the respective compositions of each sub-layer may be the same as or different from each other.

In a case where the gas barrier film of the present invention includes two or more inorganic layers, the compositions, formation methods, film thicknesses, and the like of each inorganic layer may be the same as or different from each other. The compositions of each inorganic layer are preferably the same as each other and the compositions and formation methods thereof are more preferably the same as each other.

The inorganic layer is preferably a vapor deposition layer. That is, the inorganic layer is preferably formed by a vapor deposition method or a sputtering method. The vapor deposition method includes physical vapor deposition methods (PVD) such as an ion plating method and various chemical vapor deposition methods (CVD). The inorganic layer is preferably formed by a chemical vapor deposition method (CVD).

For example, the inorganic layer can be formed on the surface of the organic layer, the surface of the silica layer, or the surface of the inorganic layer.

Examples of the chemical vapor deposition method include a plasma CVD described in paragraphs 0023 to 0044 of JP2012-097291A. The application power in the chemical vapor deposition method is 0.1 to 10 kW and the frequency of the alternate current is preferably 0.05 to 500 kHz. The vacuum degree in a vacuum chamber is preferably set to 0.5 to 100 Pa according to the kind of raw material gas or the like. The kind of the raw material gas in a case of using an organic silicon compound, the kind of gas required for the chemical vapor deposition method, and the amount thereof can be referred to, for example, the description of paragraphs 0110 to 0119 of JP2015-147952A. The raw material gas is preferably hexamethyldisiloxane or 1,1,3,3-tetramethyldisiloxane, and the gas required for the chemical vapor deposition method is preferably oxygen gas, ozone gas, nitrogen gas, or ammonia gas.

[Organic Layer]

The gas barrier film of the present invention may include an organic layer. The gas barrier film includes a first organic layer between the film substrate and the silica layer and may further include a plurality of organic layers (hereinafter, a first organic layer and/or a plurality of organic layers that may be further included in the gas barrier film may be simply referred to as “organic layer”). In the gas barrier film of the present invention, the concentration of carbon atoms in the first organic layer is 50% or more. In the present specification, the concentration of carbon atoms is a percentage of the number of carbon atoms with respect to a total number of atoms included in each organic layer. The concentration of carbon atoms is a value calculated from an atomic number ratio obtained from a value measured by an X-ray photoelectron spectroscopy method (XPS method). An XPS surface analysis device is not particularly limited and for example, an ESCALAB-200R manufactured by VG Scientific can be used.

In each organic layer, the concentration of carbon atoms is preferably 60% or more and more preferably 70% or more.

In the gas barrier film of the present invention, the atomic number ratio of the organic layer is preferably O/C=0.050 to 1.0. O/C is a number obtained by dividing the number of oxygen atoms in each organic layer by the number of carbon atoms and is a value calculated based on the atomic number ratio obtained from a value measured by an X-ray photoelectron spectroscopy method (XPS method). By providing the organic layer having such an atomic number ratio, it is possible to hardly release alcohols or water and to hardly deteriorate the silica layer and the inorganic layer. The atomic number ratio of the organic layer is more preferably O/C=0.070 to 0.80 and even more preferably O/C=0.10 to 0.70.

In the gas barrier film of the present invention, the atomic number ratio of the organic layer is preferably Si/C=0.00 to 0.10. Si/C is a number obtained by dividing the number of silicon atoms in each organic layer by the number of carbon atoms and is a value calculated based on the atomic number ratio obtained from a value measured by an X-ray photoelectron spectroscopy method (XPS method). By providing the organic layer having such an atomic number ratio, it is possible to hardly release alcohols or water and to hardly deteriorate the silica layer and the inorganic layer. The atomic number ratio of the organic layer is more preferably Si/C=0.010 to 0.095 and even more preferably Si/C=0.020 to 0.090.

The atomic number ratio of the organic layer is O/C=0.050 to 1.0 and particularly preferably Si/C=0.00 to 0.10.

The organic layer can be formed by curing the composition for forming an organic layer. The composition for forming an organic layer includes a polymerizable compound and may further include a polymerization initiator, a silane coupling agent, inorganic fine particles, and the like.

(Polymerizable Compound)

The polymerizable compound is preferably a compound having an ethylenically unsaturated bond at a terminal or a side chain, and/or a compound having epoxy or oxetane at a terminal or a side chain. It is particularly preferable that the polymerizable compound is a compound having an ethylenically unsaturated bond at a terminal or a side chain. Examples of the compound having an ethylenically unsaturated bond at a terminal or a side chain include a (meth)acrylate-based compound, an acrylamide-based compound, and maleic anhydride. Among these, a (meth)acrylate-based compound is preferable, and an acrylate-based compound is particularly preferable.

As the (meth)acrylate-based compound, for example, (meth)acrylate, urethane (meth)acrylate, polyester (meth)acrylate, epoxy (meth)acrylate, or the like is preferable.

As the (meth)acrylate-based compound, specifically, for example, a compound described in paragraphs 0024 to 0036 of JP2013-43382A, or a compound described in paragraphs 0036 to 0048 of JP2013-43384A can be used. In addition, a polyfunctional acrylic monomer having a fluorene skeleton described in WO2013/047524 can be used.

The amount of the polymerizable compound contained is preferably 50% by mass or more and more preferably 70% by mass or more with respect to the solid content of the polymerizable composition (the remainder after volatilization of the volatile content). The upper limit is not particularly limited and the amount of the polymerizable compound contained is preferably 99% by mass or less and more preferably 98% by mass or less.

Two or more polymerizable compounds may be contained in the composition for forming an organic layer.

(Polymerization Initiator)

The composition for forming an organic layer may include a polymerization initiator. In a case of using a polymerization initiator, the content thereof is preferably 0.1% by mole or more, more preferably 0.5% to 5% by mole with respect to the total amount of the compounds involved in polymerization. By adopting such a composition, a polymerization reaction via an active component generation reaction can be appropriately controlled. Examples of a photopolymerization initiator include Irgacure series (for example, IRGACURE 651, IRGACURE 754, IRGACURE 184, IRGACURE 2959, IRGACURE 907, IRGACURE 369, IRGACURE 379, and IRGACURE 819), Darocure series (for example, DAROCURE TPO and DAROCURE 1173), and Quantacure PDO, all commercially available from BASF SE, and Esacure series (for example, ESACURE TZM, ESACURE TZT, and ESACURE KTO46) all commercially available from Lamberti S.p.A.

The content of the polymerization initiator in the composition for forming an organic layer is preferably 0.1% by mole or more and more preferably 0.5% to 2.0% by mole with respect to the total amount of the polymerizable compounds.

(Silane Coupling Agent)

The composition for forming an organic layer may include a silane coupling agent. The silane coupling agent preferably has a hydrolyzable reactive group such as a methoxy group, an ethoxy group, or an acetoxy group, which is to be bonded to silicon, and a substituent which has one or more reactive groups selected from an epoxy group, a vinyl group, an amino group, a halogen group, a mercapto group, and a (meth)acryloyl group, as a substituent which is bonded to the same silicon. The silane coupling agent particularly preferably has a (meth)acryloyl group. Specific examples of the silane coupling agent include a silane coupling agent represented by Formula (1) described in WO2013/146069 and a silane coupling agent represented by Formula (I) described in WO2013/027786.

The proportion of the silane coupling agent with respect to the total solid contents of the composition for forming an organic layer (the remainder after volatilization of the volatile content) is preferably 0.0% to 50% by mass and more preferably 0.0% to 25% by mass. By setting the proportion of the silane coupling agent to be in the above range, it is possible to hardly release alcohols or water and to hardly deteriorate the silica layer and the inorganic layer under a high temperature and high humidity environment. By containing the silane coupling agent, adhesiveness with the silica layer and the inorganic layer can be improved.

(Inorganic Fine Particles)

The composition for forming an organic layer may include inorganic fine particles. As the inorganic fine particles, fine particles formed of any one or more selected from the group consisting of silicon oxide such as silica, titanium oxide, aluminum oxide, tin oxide, indium oxide, ITO, zinc oxide, zirconium oxide, magnesium oxide, calcium carbonate, talc, clay, calcined kaolin, calcined calcium silicate, hydrated calcium silicate, aluminum silicate, magnesium silicate, and calcium phosphate may be used. Particularly, silicon oxide, titanium oxide, aluminum oxide, zirconium oxide, magnesium oxide, and the like are preferably used.

The proportion of the inorganic fine particles with respect to the total solid contents of the composition for forming an organic layer (the remainder after volatilization of the volatile content) is preferably 0.0% to 50% by mass, more preferably 0.0% to 40% by mass, even more preferably 0.0% to 25% by mass, and particularly preferably 0.0% to 5% by mass. By setting the proportion of the inorganic fine particles to be in the above range, it is possible to hardly release alcohols or water and to hardly deteriorate the silica layer and the inorganic layer under a high temperature and high humidity environment.

(Solvent)

The composition for forming an organic layer may include a solvent. Examples of the solvent include ketones such as methyl ethyl ketone (MEK), or ester-based solvents: 2-butanone, propylene glycol monoethyl ether acetate (PGMEA), cyclohexanone, and a mixed solvent of any two or more solvents of these solvents. Among these, methyl ethyl ketone is preferable.

The content of the solvent of the composition for forming an organic layer is preferably 60% to 97% by mass and more preferably 70% to 95% by mass with respect to the total amount of the composition for forming an organic layer.

(Method of Preparing Organic Layer)

In order to prepare the organic layer, first, the composition for forming an organic layer is applied in the form of a layer. In order to apply the composition in the form of a layer, the composition for forming an organic layer may be applied on the film substrate. The application of the composition may be performed on the film substrate surface or the inorganic layer surface. Examples of the method for application include a dip coating method, an air knife coating method, a curtain coating method, a roller coating method, a wire bar coating method, a gravure coating method, a slide coating method or an extrusion coating method (also referred to as a die coating method) using a hopper described in U.S. Pat. No. 2,681,294A and among these, an extrusion coating method can be preferably adopted.

The composition for forming an organic layer may be dried as a coating film after the composition is applied.

The composition for forming an organic layer may be cured by light (such as ultraviolet rays), electron beams or heat rays and is preferably cured by light. Particularly, it is preferable that while the composition for forming an organic layer is being heated at a temperature of 25° C. or higher (for example, 30° C. to 130° C.), the composition is cured. By promoting the free motion of the composition for forming an organic layer by heating, the composition can be effectively cured, and the film can be formed without damaging the film substrate or the like.

The light for irradiation may be ultraviolet rays from a high pressure mercury lamp or a low pressure mercury lamp. The irradiation energy is preferably 0.1 J/cm² or more and more preferably 0.5 J/cm² or more.

It is preferable that an oxygen concentration or oxygen partial pressure in the polymerization is set to be low since the polymerizable compound suffers polymerization inhibition by oxygen in the air. In a case of reducing the oxygen concentration at the time of the polymerization by a nitrogen substitution method, the oxygen concentration is preferably 2% or less and more preferably 0.5% or less. In a case where the oxygen partial pressure at the time of the polymerization is to be reduced by a pressure reducing method, the total pressure is preferably 1000 Pa or less and more preferably 100 Pa or less.

The polymerization rate of the polymerizable compound in the composition for forming an organic layer after curing is preferably 20% by mass or more, more preferably 30% by mass or more, and particularly preferably 50% by mass or more. The polymerization rate denoted here means a proportion of reacted polymerizable groups among all the polymerizable groups (such as acryloyl group and methacryloyl group) in the monomer mixture. The polymerization rate can be determined quantitatively by an infrared absorption method.

It is preferable that the organic layer is smooth and has a high film hardness. The smoothness of the organic layer is preferably less than 3 nm and more preferably less than 1 nm as an average roughness in 1 μm square (Ra value).

Although the film thickness of the organic layer is not particularly limited, from the viewpoint of brittleness and light transmittance, the film thickness is preferably 0.5 μm to 10 μm and more preferably 0.7 μm to 5 μm.

The gas barrier film of the present invention may include a second organic layer. The gas barrier film preferably includes the second organic layer such that the film substrate, the first organic layer, the silica layer, the inorganic layer, and the second organic layer are arranged in this order and the second organic layer is preferably the outermost layer with respect to all of the silica layer, the inorganic layer, and the organic layer included in the gas barrier film. The gas barrier film of the present invention may include a third or higher organic layer. The second or higher organic layer may be the same as or different from the first organic layer. The concentration of carbon atoms may not be in the above range and the second or higher organic layer may be different from the first organic layer. However, it is preferable that the concentration of carbon atoms is in the above range. In addition, preferable ranges of O/C and Si/C are the same as the above preferable ranges of those of the first organic layer.

[Use of Gas Barrier Film]

The gas barrier film of the present invention can be preferably used in a device or an optical member of which the performance is deteriorated by chemical components in air (oxygen, water, nitrogen oxides, sulfur oxides, ozone, and the like). Examples of the device include electronic devices such as organic EL elements, liquid crystal display elements, thin film transistors, touch panels, electronic papers, and solar cells. The gas barrier film is preferably used in an organic EL element.

The gas barrier film of the present invention can be used for film sealing of devices. In addition, the gas barrier film of the present invention can be used as a film for sealing of a device substrate or for sealing using a solid sealing method. The solid sealing method is a method in which a protective layer is formed on a device and then an adhesive layer and a gas barrier film are overlapped and cured. The adhesive is not particularly limited, and examples thereof include a thermosetting epoxy resin and a photocurable acrylate resin.

(Organic EL Element)

Examples of the organic EL element in which the gas barrier film is used are specifically described in JP2007-30387A.

(Liquid Crystal Display Element)

A reflective type liquid crystal display device is configured to include, in order from the lower side, a lower substrate, a reflection electrode, a lower alignment film, a liquid crystal layer, an upper alignment film, a transparent electrode, an upper substrate, a λ/4 plate, and a polarizing film. In the present invention, the gas barrier film can be used as the transparent electrode substrate and the upper substrate. In a case of a color display, it is preferable to further provide a color filter layer between the reflection electrode and the lower alignment film or between the upper alignment film and the transparent electrode. A transmission type liquid crystal display device is configured to include, in order from the lower side, a backlight, a polarizing plate, a λ/4 plate, a lower transparent electrode, a lower alignment film, a liquid crystal layer, an upper alignment film, an upper transparent electrode, an upper substrate, a λ/4 plate, and a polarizing film. Of these, the substrate including a barrier laminate or the gas barrier film of the present invention can be used as the upper transparent electrode and the upper substrate. In a case of a color display, it is preferable to further provide a color filter layer between the lower transparent electrode and the lower alignment film or between the upper alignment film and the transparent electrode. The kind of the liquid crystal cell is not particularly limited, and a twisted nematic (TN) type, a super twisted nematic (STN) type, or a hybrid aligned nematic (HAN) type, a vertical alignment (VA) type, an electrically controlled birefringence (ECB) type, an optically compensated bend (OCB) type, a continuous pinwheel alignment (CPA) type, and an in-plane switching (IPS) are preferable.

(Others)

Other application examples include a thin film transistor described in JP1998-512104A (JP-H10-512104A), touch panels described in JP1993-127822A (JP-H05-127822A), JP2002-48913A, and the like, an electronic paper described in JP2000-98326A, and a solar cell described in JP1997-018042A (JP-H09-018042A).

(Optical Member)

Examples of the optical member in which the gas barrier film of the present invention is used include a circularly polarizing plate.

A λ/4 plate and a polarizing plate can be laminated on the gas barrier film of the present invention as a substrate to prepare a circularly polarizing plate. In this case, the lamination is performed such that an angle between a slow axis of the λ/4 plate and an absorption axis of the polarizing plate is 45°. It is preferable that such a polarizing plate is stretched in a 45° direction with respect to a longitudinal direction (MD). For example, a polarizing plate described in JP2002-865554A can be suitably used.

### EXAMPLES

The present invention is described with greater specificity below through Examples. The materials, amounts used, ratios, processing contents, processing procedures, and the like that are indicated in the Examples below can be suitably modified without departing from the spirit of the present invention. Accordingly, the scope of the present invention is not limited by the specific examples given below.

<Preparation of Gas Barrier Film of Example 1>

[Formation of Organic Layer]

To polyethylene naphthalate film (PEN, TEONEX Q65FA, manufactured by Teijin DuPont, thickness: 100 μm), a polymerizable composition including a polymerizable compound (TMPTA: trimethylol propane triacrylate, manufactured by Daicel-Allnex Ltd.), a photopolymerization initiator (IRGACURE 819, manufactured by BASF SE), and a 2-butanone (TMPTA:IRGACURE 819:2-butanone=19.4:0.6:80 at a mass ratio) was applied with a wire bar and the polymerizable composition was dried at 80° C. for 3 minutes. Next, the dried polymerizable composition was irradiated with ultraviolet rays using a high pressure mercury lamp (irradiation dose: 0.5 J/cm²) in a nitrogen atmosphere at an oxygen content of 100 ppm or less to cure the polymerizable composition. Thus, an organic layer having a thickness of 4 μm was prepared.

[Formation of Silica Layer]

A coating liquid A was applied to the surface of the organic layer by a spin coating method and then the coating layer was dried at 80° C. for 1 minute. The dried coating layer was subjected to an irradiation treatment under Condition A and thus a laminate provided with a silica layer having a thickness of 250 nm was obtained.

(Coating Liquid A)

A perhydropolysilazane (PHPS) solution (PHPS: 20% by mass, dibutyl ether: 80% by mass) and an amine solution (N,N,N′,N′-tetramethyl-1,6-diaminohexane: 5% by mass, dibutyl ether: 95% by mass) were mixed to prepare a coating solution such that the mass ratio between perhydropolysilazane and N,N,N′,N′-tetramethyl-1,6-diaminohexane was 100:1. Then, the mixture was diluted with dibutyl ether such that the mass percent of the coating liquid A became 10% by mass. Thus, a coating liquid A was obtained.

(Condition A)

Using a stage movable Xenon excimer irradiation device (MECL-M-1-200, manufactured by M.D. Excimer Inc.), the irradiation treatment was performed under the following conditions. In addition, the oxygen concentration was adjusted according to a nitrogen gas/oxygen gas flow ratio of a gas to be introduced into an irradiation chamber obtained by measuring the flow rate of nitrogen gas and oxygen gas to be introduced in the irradiation chamber using a flow meter.

Irradiance: 140 mW/cm² (main peak emission wavelength: 172 nm)

Stage temperature: 100° C.

Distance between sample and light source: 1 mm

Treatment environment: dry nitrogen gas atmosphere

Oxygen concentration of treatment environment: 0.1% by volume

Stage moving speed: 10 mm/sec

Excimer exposure light cumulative amount: 6500 mJ/cm²

[Preparation of Inorganic Layer]

An inorganic layer having a thickness of 250 nm was provided on the surface of the silica layer under Condition B to obtain a laminate (Condition B).

Polyethylene naphthalate film (PEN, TEONEX Q65FA, manufactured by Teijin DuPont) was bonded to the laminate in the longitudinal direction to prepare a roll. The inorganic layer was provided on the surface of the silica layer using a device shown in FIG. 1 of JP2012-97291A under the following film formation conditions.

(Film Formation Conditions)

Supply amount of raw material gas (HMDSO: hexamethyldisiloxane): 25 ml/min

Supply amount of oxygen gas (O₂): 500 ml/min

Vacuum degree in vacuum chamber: 2 Pa

Application power from power source for generating plasma: 1.2 kW

Frequency of power source for generating plasma: 80 kHz

Transport speed of film: 0.5 m/min

<Preparation of Gas Barrier Films of Examples 2 to 7 and Comparative Examples 1 and 2>

Gas barrier films of Examples 2 to 7 and Comparative Examples 1 and 2 were prepared in the same procedure as in the preparation of the gas barrier film of Example 1 except that the organic layer was formed as follows.

### Example 2

A gas barrier film was prepared in the same manner as in Example 1 except that the polymerizable compound of the organic layer was changed from TMPTA to A-DCP manufactured by Shin-Nakamura Chemical Co., Ltd.

### Example 3

A gas barrier film was prepared in the same manner as in Example 1 except that the polymerizable compound of the organic layer was changed to a mixed compound of TMPTA and KBM5103 manufactured by Shin-Etsu Chemical Co., Ltd. (TMPTA:KBM5103=80:20 in mass ratio).

### Example 4

A gas barrier film was prepared in the same manner as in Example 1 except that the polymerizable compound of the organic layer was changed to a mixed compound of A-DCP and KBM5103 (A-DCP:KBM5103=80:20 in mass ratio).

### Example 5

A gas barrier film was prepared in the same manner as in Example 1 except that the polymerizable compound of the organic layer was changed from TMPTA to M-305 manufactured by Toagosei Co., Ltd.

### Example 6

A gas barrier film was prepared in the same manner as in Example 1 except that the polymerizable compound of the organic layer was changed to a mixed compound of TMPTA and KBM5103 manufactured by Shin-Etsu Chemical Co., Ltd. (TMPTA:KBM5103=50:50 in mass ratio).

### Example 7

A gas barrier film was prepared in the same manner as in Example 1 except that to the polymerizable composition used in Example 1, silica particle (MEK-ST-40, manufactured by Nissan Chemical Industries, Limited, particle diameter: 10 to 15 nm, solid content concentration: 40% by mass) were further added to form a polymerizable composition (TMPTA:MEK-ST-40:IRGACURE819:2-butanone=15.5:9.8:0.6:74.1 in mass ratio).

### Comparative Example 1

A gas barrier film was prepared in the same manner as in Example 7 except that the polymerizable compound of the organic layer was changed from TMPTA to M-240 manufactured by Toagosei Co., Ltd.

### Comparative Example 2

A gas barrier film was prepared in the same manner as in Example 7 except that the mass ratio in the polymerizable composition was changed to TMPTA:MEK-ST-40:IRGACURE819:2-butanone=9.7:24.3:0.6:65.4.

<Evaluation of Gas Barrier Film>

(Measurement of Water Vapor Transmission Rate)

The water vapor transmission rate [g/(m²·day)] of each of the gas barrier films obtained was measured by a calcium corrosion method (a method described in JP2005-283561A). The water vapor transmission rate immediately after preparation was set to WVTR(0), and the water vapor transmission rate after the film was left to stand under an environment of 85° C. and 85% RH for 250 hours was set to WVTR(1). The results are shown in Table 1.

(Measurement of Atomic Number Ratio of Silica Layer (Si:O:N))

The surface of the silica layer before the inorganic layer was formed was used to measure the atomic number ratio of the silica layer by an XPS method. In the XPS, an ESCALAB-200R manufactured by VG Scientific was used. As an X-ray anode, Mg was used and measurement was performed at an output of 600 W (accelerating voltage: 15 kV, emission current: 40 mA). The results are shown in Table 1.

(Measurement of Atomic Number Ratio (Si:O:C) of Organic Layer)

The surface of the organic layer before the silica layer was formed was used to evaluate the atomic number ratio of the organic layer by an XPS method in the same manner as in the measurement of the atomic number ratio of the silica layer. In the table, the concentration of the carbon atoms of the organic layer is denoted as “C percentage”.

TABLE 1

| | C percentage | O/C | Si/C | WVTR(0) | WVTR(1) | WVTR(0)/WVTR(1) |
|---|---|---|---|---|---|---|
| Example 1 | 67 | 0.48 | 0.00 | 2 × 10⁻⁵ | 6 × 10⁻⁵ | 0.33 |
| Example 2 | 82 | 0.22 | 0.00 | 2 × 10⁻⁵ | 5 × 10⁻⁵ | 0.40 |
| Example 3 | 65 | 0.51 | 0.02 | 2 × 10⁻⁵ | 6 × 10⁻⁵ | 0.33 |
| Example 4 | 78 | 0.27 | 0.02 | 2 × 10⁻⁵ | 4 × 10⁻⁵ | 0.50 |
| Example 5 | 62 | 0.58 | 0.00 | 2 × 10⁻⁵ | 1 × 10⁻⁴ | 0.20 |
| Example 6 | 64 | 0.52 | 0.05 | 2 × 10⁻⁵ | 2 × 10⁻⁴ | 0.10 |
| Example 7 | 57 | 0.68 | 0.09 | 2 × 10⁻⁵ | 2 × 10⁻⁴ | 0.10 |
| Comparative | 45 | 1.09 | 0.14 | 2 × 10⁻⁶ | 5 × 10⁻⁴ | 0.04 |
| Example 1 | | | | | | |
| Comparative | 39 | 1.20 | 0.35 | 2 × 10⁻⁵ | 6 × 10⁻⁴ | 0.03 |
| Example 2 | | | | | | |

<Preparation of Gas Barrier Films of Examples 11 to 17 and Comparative Examples 11 and 12>

Gas barrier films of Examples 11 to 17 and Comparative Examples 11 and 12 were prepared respectively in the same manner as in the preparation of the gas barrier films of Examples 1 to 7 and Comparative Examples 1 and 2 except that instead of using the amine solution of the coating liquid A used for forming the silica layer, another amine solution (trihexylamine: 5% by mass, dibutyl ether: 95% by mass) was used and a coating liquid was prepared such that the mass ratio of perhydropolysilazane and trihexylamine became 100:1, and were evaluated in the same manner. The results are shown in Table 2.

TABLE 2

| | C percentage | O/C | Si/C | WVTR(0) | WVTR(1) | WVTR(0)/WVTR(1) |
|---|---|---|---|---|---|---|
| Example11 | 67 | 0.48 | 0.00 | 2 × 10⁻⁵ | 5 × 10⁻⁵ | 0.40 |
| Example12 | 82 | 0.22 | 0.00 | 2 × 10⁻⁵ | 4 × 10⁻⁵ | 0.50 |
| Example13 | 65 | 0.51 | 0.02 | 2 × 10⁻⁵ | 4 × 10⁻⁵ | 0.50 |
| Example14 | 78 | 0.27 | 0.02 | 2 × 10⁻⁵ | 3 × 10⁻⁵ | 0.67 |
| Example15 | 62 | 0.58 | 0.00 | 2 × 10⁻⁵ | 8 × 10⁻⁵ | 0.25 |
| Example16 | 64 | 0.52 | 0.05 | 2 × 10⁻⁵ | 8 × 10⁻⁵ | 0.25 |
| Example17 | 57 | 0.68 | 0.09 | 2 × 10⁻⁵ | 1 × 10⁻⁴ | 0.20 |
| Comparative | 45 | 1.09 | 0.14 | 2 × 10⁻⁶ | 3 × 10⁻⁴ | 0.07 |
| Example 11 | | | | | | |
| Comparative | 39 | 1.20 | 0.35 | 2 × 10⁻⁵ | 4 × 10⁻⁴ | 0.05 |
| Example 12 | | | | | | |

What is claimed is:

1. A gas barrier film comprising, in order:
a film substrate;
a first organic layer; and
a silica layer,
wherein the silica layer includes a silica polymer having at least a covalent bond between a silicon atom and an oxygen atom, and
a concentration of carbon atoms of the first organic layer is 50% or more.

2. The gas barrier film according to claim 1,
wherein the first organic layer is in direct contact with the silica layer.

3. The gas barrier film according to claim 1, further comprising:
an inorganic layer,
wherein the first organic layer is in direct contact with the inorganic layer.

4. The gas barrier film according to claim 1, further comprising:
an inorganic layer,
wherein the film substrate, the first organic layer, the silica layer, and the inorganic layer are provided in this order.

5. The gas barrier film according to claim 3,
wherein the inorganic layer is a vapor deposition layer.

6. The gas barrier film according to claim 4,
wherein the inorganic layer is a vapor deposition layer.

7. The gas barrier film according to claim 1,
wherein an atomic number ratio of the first organic layer is O/C=0.050 to 1.0 and Si/C=0.00 to 0.10.

8. The gas barrier film according to claim 1,
wherein a film thickness of the first organic layer is 0.5 to 10 μm.

9. The gas barrier film according to claim 1,
wherein a film thickness of the silica layer is 50 to 1000 nm.

10. The gas barrier film according to claim 1,
wherein an atomic number ratio of the silica layer is Si:O:N=1:0.1 to 1.2:0.5 to 1.5.

11. The gas barrier film according to claim 1, further comprising:
an inorganic layer; and
a second organic layer,
wherein the film substrate, the first organic layer, the silica layer, the inorganic layer, and the second organic layer are provided in this order, and
a concentration of carbon atoms of the second organic layer is 50% or more.

12. A method of producing a gas barrier film comprising:
forming an organic layer having a concentration of carbon atoms of 50% or more on a film substrate;
applying a coating liquid including a silicon compound to the organic layer to form a coating layer including the silicon compound; and
irradiating the coating layer including the silicon compound with vacuum ultraviolet rays to form a silica layer including a silica polymer having at least a covalent bond between a silicon atom and an oxygen atom.

13. The method of producing a gas barrier film according to claim 12,
wherein the applying of the coating liquid includes applying the coating liquid to a surface of the organic layer, and
the method further comprises forming an inorganic layer on a surface of the silica layer by a vapor deposition method or a sputtering method.

14. The method of producing a gas barrier film according to claim 12, further comprising:
forming an inorganic layer on a surface of the organic layer by a vapor deposition method or a sputtering method,
wherein the applying of the coating liquid includes applying the coating liquid to a surface of the inorganic layer.

15. The method of producing a gas barrier film according to claim 13,
wherein the inorganic layer is formed by a chemical vapor deposition method.

16. The method of producing a gas barrier film according to claim 14,
wherein the inorganic layer is formed by a chemical vapor deposition method.

17. The method of producing a gas barrier film according to claim 12,
wherein the silicon compound is perhydropolysilazane.

18. The method of producing a gas barrier film according to claim 12,
wherein an atomic number ratio of the organic layer is O/C=0.050 to 1.0 and Si/C=0 to 0.1.
